(19) United States
(12) Patent Application Publication
(10) Pub. No.: US 2025/0241158 A1
(43) Pub. Date: Jul. 24, 2025

(54) DISPLAY DEVICE

(71) Applicant: Sharp Display Technology Corporation, Kameyama City, Mie (JP)

(72) Inventors: Jun SAKUMA, Kameyama City, Mie (JP); Yasushi ASAOKA, Kameyama City, Mie (JP)

(21) Appl. No.: 18/697,927

(22) PCT Filed: Dec. 7, 2021
(86) PCT No.: PCT/JP2021/044899

§ 371 Date: Apr. 2, 2024

(51) Int. Cl. H10K 59/35; H10K 59/122; H10K 59/38

(52) U.S. Cl. CPC H10K 59/353; H10K 59/122; H10K 59/38

(57) ABSTRACT

A display device includes: a red light-emitting layer configured to emit red light, a green light-emitting layer configured to emit green light, a first blue light-emitting layer configured to emit first blue light, and a second blue light-emitting layer configured to emit second blue light, the red light-emitting layer, the green light-emitting layer, the first blue light-emitting layer, and the second blue light-emitting layer being individually provided in a cross-sectional view of the display device; and a yellow-wavelength conversion layer provided over at least the second blue light-emitting layer, and configured to convert the second blue light into yellow light.

### TECHNICAL FIELD

The present disclosure relates to a display device.

### BACKGROUND ART

Display devices have been required to emit high-luminance white light. To obtain high-luminance white light, combining blue light and yellow light together to form white light is preferable.

As an example display device that can emit blue light and yellow light, Patent Literatures 1 and 2 each disclose a display device including a structure that emits blue light, and a yellow light-emitting layer, which is a light-emitting layer that emits yellow light.

### CITATION LIST

### Patent Literatures

Patent Literature 1: International Publication No. 2019/098073
Patent Literature 2: Japanese Unexamined Patent Application Publication No. 2019-083203

### SUMMARY

### Technical Field

Developments of light-emitting materials that emit high-luminance yellow light have been unsatisfactory. This unsatisfactory situation has been prominent particularly in electroluminescence materials for organic light-emitting diode (OLED) display devices and quantum-dot light-emitting diode (QLED) display devices.

As such, it is technically difficult for display devices according to known techniques to achieve a yellow light-emitting layer that emits high-luminance yellow light, and thus, it is unfortunately difficult for these devices to emit high-luminance white light.

### Solution to Problem

A display device according to one aspect of the present disclosure includes the following: a red light-emitting layer configured to emit red light, a green light-emitting layer configured to emit green light, a first blue light-emitting layer configured to emit first blue light, and a second blue light-emitting layer configured to emit second blue light, the red light-emitting layer, the green light-emitting layer, the first blue light-emitting layer, and the second blue light-emitting layer being individually provided in the cross-sectional view of the display device; and a yellow-wavelength conversion layer provided over at least the second blue light-emitting layer, and configured to convert the second blue light into yellow light.

### Advantageous Effect of Disclosure

The aspect of the present disclosure facilitates emission of high-luminance white light.

### BRIEF DESCRIPTION OF DRAWINGS

FIG. 1 is a sectional view of a schematic configuration of a display device according to a first embodiment of the present disclosure.

FIG. 2 is a graph showing the relationship between wavelengths of light (horizontal axis) and relative values of the standard photopic luminous efficiency of light (vertical axis).

FIG. 3 is a sectional view of a schematic configuration of a display device according to a second embodiment of the present disclosure.

FIG. 4 is a sectional view of a schematic configuration of a display device according to a third embodiment of the present disclosure.

FIG. 5 is a graph showing an example spectrum of light that is emitted by a yellow light-emitting portion.

FIG. 6 is a graph showing another example spectrum of light that is emitted by the yellow light-emitting portion.

### DESCRIPTION OF EMBODIMENTS

Embodiments of the present disclosure will be described below. It is noted that for convenience in description, components having the same functions as those of earlier described components will be denoted by the same signs, and that their description will not be repeated in some cases.

### First Embodiment

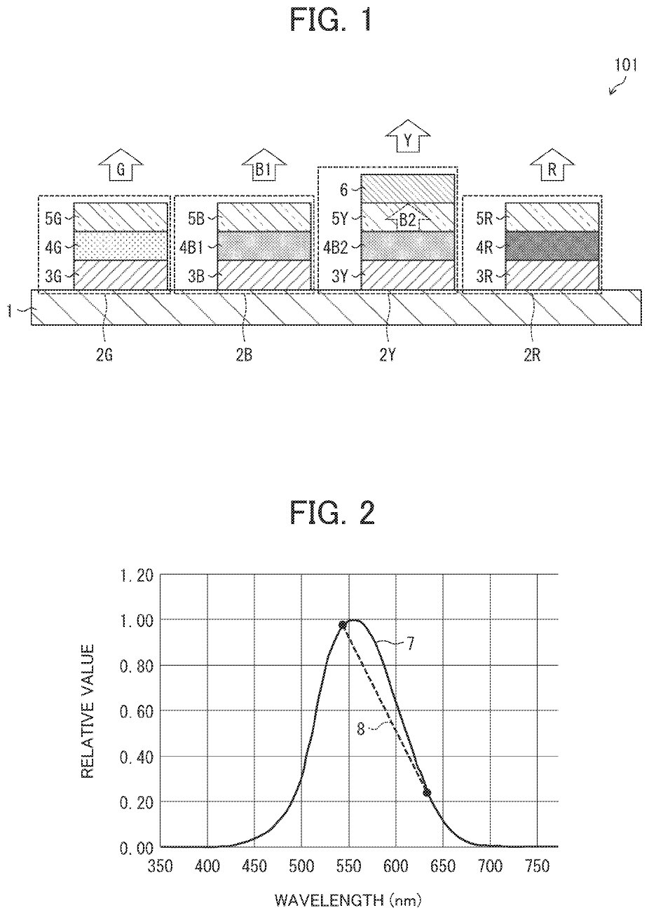

FIG. 1 is a sectional view of a schematic configuration of a display device 101 according to a first embodiment of the present disclosure. The display device 101 includes a substrate 1, a red light-emitting portion 2R, a green light-emitting portion 2G, a blue light-emitting portion 2B, and a yellow light-emitting portion 2Y. The red light-emitting portion 2R, the green light-emitting portion 2G, the blue light-emitting portion 2B, and the yellow light-emitting portion 2Y are provided on the substrate 1 and are individually provided in the cross-sectional view of the display device 101.

The red light-emitting portion 2R has a reflective electrode 3R, a red light-emitting layer 4R that emits red light R, and a transparent electrode 5R. The reflective electrode 3R, the red light-emitting layer 4R, and the transparent electrode 5R are stacked in the stated order on the substrate 1. The red light-emitting layer 4R emits the red light R in response to a current that flows between the reflective electrode 3R and transparent electrode 5R and is composed of, for instance, an OLED or a QLED. The red light R is defined as light whose peak wavelength ranges from 600 nm inclusive to 700 nm exclusive.

The green light-emitting portion 2G has a reflective electrode 3G, a green light-emitting layer 4G that emits green light G, and a transparent electrode 5G. The reflective electrode 3G, the green light-emitting layer 4G, and the transparent electrode 5G are stacked in the stated order on the substrate 1. The green light-emitting layer 4G emits the green light G in response to a current that flows between the reflective electrode 3G and transparent electrode 5G and is composed of, for instance, an OLED or a QLED. The green light G is defined as light whose peak wavelength ranges from 490 nm inclusive to 555 nm exclusive.

The blue light-emitting portion 2B has a reflective electrode 3B, a first blue light-emitting layer 4B1 that emits first blue light B1, and a transparent electrode 5B. The reflective electrode 3B, the first blue light-emitting layer 4B1, and the transparent electrode 5B are stacked in the stated order on the substrate 1. The first blue light-emitting layer 4B1 emits the first blue light B1 in response to a current that flows between the reflective electrode 3B and transparent electrode 5B and is composed of, for instance, an OLED or a QLED. The first blue light B1 is defined as light whose peak wavelength ranges from 400 nm inclusive to 490 nm exclusive.

The yellow light-emitting portion 2Y has a reflective electrode 3Y, a second blue light-emitting layer 4B2 that emits second blue light B2, and a transparent electrode 5Y. The reflective electrode 3Y, the second blue light-emitting layer 4B2, and the transparent electrode 5Y are stacked in the stated order on the substrate 1. The second blue light-emitting layer 4B2 emits the second blue light B2 in response to a current that flows between the reflective electrode 3Y and transparent electrode 5Y and is composed of, for instance, an OLED or a QLED. The second blue light B2 is defined as light whose peak wavelength ranges from 400 nm inclusive to 490 nm exclusive.

The emission spectrum of the first blue light-emitting layer 4B1 and the emission spectrum of the second blue light-emitting layer 4B2 may be the same or different from each other. To be specific, the peak wavelength of the first blue light B1 and the peak wavelength of the second blue light B2 may be the same or different from each other.

Each of the reflective electrodes 3R, 3G, 3B, and 3Y is a light-reflective electrode. Each of the transparent electrodes 5R, 5G, 5B, and 5Y is a light-transparent electrode. Each of the reflective electrodes 3R, 3G, 3G, and 3Y may be replaced with a light-transparent electrode, and at this time, the substrate 1 may be light-transparent as well.

A carrier functional layer may be formed as necessary between the reflective electrode 3R and red light-emitting layer 4R, and between the red light-emitting layer 4R and transparent electrode 5R. A carrier functional layer may be formed as necessary between the reflective electrode 3G and green light-emitting layer 4G, and between the green light-emitting layer 4G and transparent electrode 5G. A carrier functional layer may be formed as necessary between the reflective electrode 3B and first blue light-emitting layer 4B1, and between the first blue light-emitting layer 4B1 and transparent electrode 5B. A carrier functional layer may be formed as necessary between the reflective electrode 3Y and second blue light-emitting layer 4B2, and between the second blue light-emitting layer 4B2 and transparent electrode 5Y. Examples of the carrier functional layers include a hole injection layer, a hole transport layer, an electron injection layer, and an electron transport layer.

In the display device 101, the red light-emitting layer 4R that emits the red light R, the green light-emitting 4G that emits the green light G, the first blue light-emitting layer 4B1 that emits the first blue light B1, and the second blue light-emitting layer 4B2 that emits the second blue light B2 are individually provided in the cross-sectional view of the display device 101. For instance, the red light-emitting layer 4R, the green light-emitting 4G, the first blue light-emitting layer 4B1, and the second blue light-emitting layer 4B2 are color-coded separately from each other and are thus provided in the form of an island.

The yellow light-emitting portion 2Y further has a yellow-wavelength conversion layer 6. The yellow-wavelength conversion layer 6 is provided over at least the second blue light-emitting layer 4B2 and is stacked on the transparent electrode 5Y in FIG. 1. The yellow-wavelength conversion layer 6 converts the second blue light B2 into yellow light Y, and this layer mainly subjects the second blue light B2 emitted by the second blue light-emitting layer 4B2 to wavelength conversion and emits the yellow light Y obtained through the wavelength conversion. The yellow light Y is defined as light whose peak wavelength ranges from 555 nm inclusive to 600 nm exclusive.

The display device 101 can emit the yellow light Y by using an electroluminescence material that emits the second blue light B2 at high efficiency, and a photoluminescence material that emits the yellow light Y at high efficiency, rather than by using an electroluminescence material that emits yellow light at high efficiency. Accordingly, the display device 101 can easily emit the yellow light Y of high luminance. By extension, the display device 101 can easily emit high-luminance white light by combining the high-luminance yellow light Y and the first blue light B1 together to form white light.

The yellow-wavelength conversion layer 6 preferably contains a quantum dot material. This enables the display device 101 to emit the yellow light Y of high luminance more easily. The quantum dot material contained in the yellow-wavelength conversion layer 6 preferably has a core made of indium phosphide (InP). This can achieve the yellow-wavelength conversion layer 6 complied with the Restriction of Hazardous Substances (RoHS) Directive.

The second blue light-emitting layer 4B2 is preferably composed of a quantum-dot light-emitting diode (i.e., a QLED). Consequently, the second blue light B2 of high luminance can be emitted, enabling the display device 101 to emit the yellow light Y of high luminance more easily.

At least one of the red light-emitting layer 4R and green light-emitting layer 4G is preferably composed of a quantum-dot light-emitting diode (i.e., a QLED). This can achieve the display device 101 that can emit high-luminance and wide-color-gamut light.

FIG. 2 is a graph showing the relationship between wavelengths of light (horizontal axis) and relative values of the standard photopic luminous efficiency of light (vertical axis). In FIG. 2, the relative values of the standard photopic luminous efficiency of light are expressed by a curved line 7, which has a peak at light wavelength 555 nm.

It has been known that yellow light is formed by combining the red light R and green light G together. Hereinafter, yellow light having a single emission peak will be referred to as “single yellow light”, and yellow light formed by combining the red light R and green light G together will be referred to as “combined-color yellow light”. The relative values of the standard photopic luminous efficiency of the single yellow light are on the curved line 7 of the standard photopic luminous efficiency in FIG. 2. The relative values of the standard photopic luminous efficiency of the combined-color yellow light are the averages between the relative values of the standard photopic luminous efficiency of the red light R, and the relative values of the standard photopic luminous efficiency of the green light G and are on a straight line 8 of the standard photopic luminous efficiency in FIG. 2.

Comparison between the curved line 7 and straight line 8 reveals that the relative values of the standard photopic luminous efficiency of the combined-color yellow light are lower than the relative values of the standard photopic luminous efficiency of the single yellow light. This reveals that the single yellow light can achieve high luminance for a user more easily than the combined-color yellow light. This also reveals that as large an amount ratio of the single yellow light as possible to the amount of the combined-color yellow light can offer high-luminance yellow light to the user by the use of less energy.

The energy conversion efficiency of the yellow-wavelength conversion layer 6 will be denoted by Ey. Ey is defined by the ratio of whole light energy that is radiated from a certain substance to light energy that is absorbed by the certain substance, at the time when the certain substance is caused to absorb monochromatic light having a peak that is the peak wavelength of the second blue light B2.

The standard photopic luminous efficiency of the yellow light Y that is emitted from the yellow-wavelength conversion layer 6 will be denoted by Sy. Sy is defined by the standard photopic luminous efficiency at the peak wavelength of the yellow light Y.

The average between the standard photopic luminous efficiency of the red light R that is emitted from the red light-emitting layer 4R, and the standard photopic luminous efficiency of the green light G that is emitted from the green light-emitting layer 4G will be denoted by Srg. Srg is defined as Srg=((λr−λy)*Sg+(λy−λg)*Sr)/(λr−λg), where Sr is the standard photopic luminous efficiency at a peak wavelength λr of the red light R, where Sg is the standard photopic luminous efficiency at a peak wavelength λg of the green light G, where λy is the peak wavelength of the yellow light Y that is emitted from the yellow-wavelength conversion layer 6.

With regard to Ey, Sy, and Srg above, Srg/Sy<Ey is preferably satisfied.

The yellow light Y that is emitted from the yellow-wavelength conversion layer 6 preferably has a peak wavelength of 570 nm, and the first blue light B1 that is emitted from the first blue light-emitting layer 4B1 preferably has a peak wavelength of 450 nm. This enables emission of white light of sufficiently high luminance. It is noted that each of 570 nm and 450 nm herein is a wavelength rounded off to the nearest integer. That is, 570 nm means, to be exact, 569.5 nm inclusive to 570.5 nm exclusive, and 450 nm means, to be exact, 449.5 nm inclusive to 450.5 nm exclusive.

### Second Embodiment

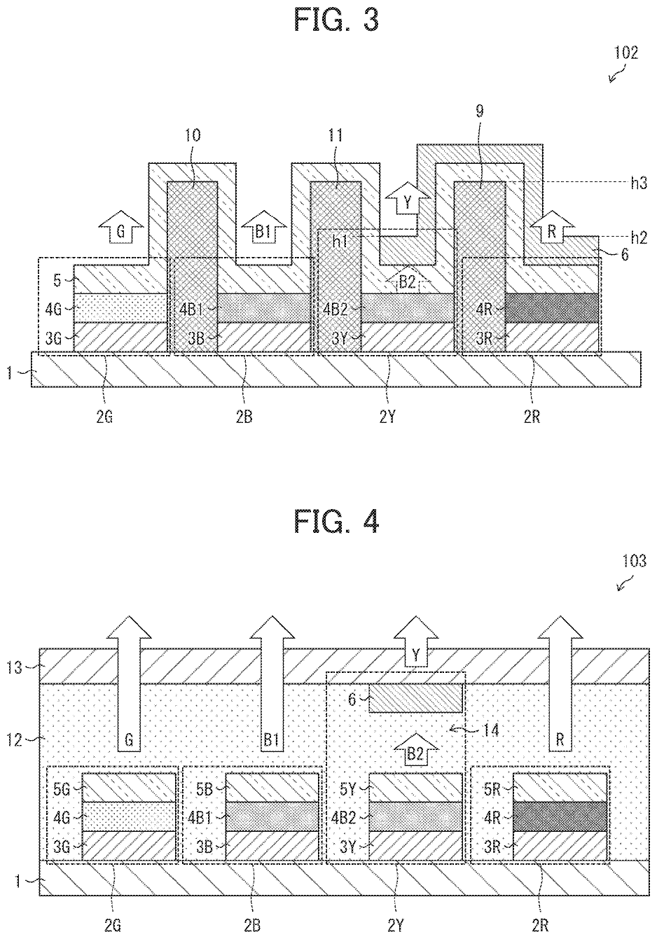

FIG. 3 is a sectional view of a schematic configuration of a display device 102 according to a second embodiment of the present disclosure. The configuration of the display device 102 is the same as the configuration of the display device 101 with the exception of the following regard.

The display device 102 includes a bank 9. The bank 9 is disposed between the second blue light-emitting layer 4B2 and a particular light-emitting layer. The particular light-emitting layer is the red light-emitting layer 4R or the green light-emitting layer 4G. The particular light-emitting layer in FIG. 3 is the red light-emitting layer 4R.

The yellow-wavelength conversion layer 6 is continuously provided over the second blue light-emitting layer 4B2, the bank 9, and the red light-emitting layer 4R. Each of a height h1 in the lowest region of the yellow-wavelength conversion layer 6 over the second blue light-emitting layer 4B2, and a height h2 in the lowest region of the yellow-wavelength conversion layer 6 over the red light-emitting layer 4R is lower than a height h3 at the peak of the bank 9.

It is noted that in the display device 102, the yellow-wavelength conversion layer 6 over the second blue light-emitting layer 4B2 has, along the bank 9, a portion as high as or higher than the height 3, because the yellow-wavelength conversion layer 6 extends over the bank 9. Likewise, in the display device 102, the yellow-wavelength conversion layer 6 over the red light-emitting layer 4R has, along the bank 9, a portion as high as or higher than the height 3, because of the foregoing structure. That is, each of a part of the height (e.g., height 1) of the yellow-wavelength conversion layer 6 over the second blue light-emitting layer 4B2, and a part of the height (e.g., height 2) of the yellow-wavelength conversion layer 6 over the red light-emitting layer 4R is lower than the height 3 at the peak of the bank 9.

However, if possible in configuration, the whole height of the yellow-wavelength conversion layer 6 over the second blue light-emitting layer 4B2 is preferably lower than the height h3 at the peak of the bank 9. Likewise, if possible in configuration, the whole height of the yellow-wavelength conversion layer 6 over the red light-emitting layer 4R is preferably lower than the height h3 at the peak of the bank 9. Such a configuration is feasible by forming the side surface of a bank corresponding to the bank 9 into a gently sloped surface.

The foregoing configuration can increase the size of the yellow-wavelength conversion layer 6. Consequently, the display device 102 that is mechanically stable can be achieved, enabling improvement in the yield of the display device 102, and enabling the display device 102 to have a long life.

In addition, the foregoing configuration, in which the height h3 is larger than both of the heights h1 and h2, can prevent mutual interference between the yellow light Y emitted from the yellow-wavelength conversion layer 6 over the second blue light-emitting layer 4B2, and the red light R emitted from the red light-emitting layer 4R.

The display device 102 includes banks 10 and 11 in addition to the bank 9. The bank 10 is disposed between the green light-emitting layer 4G and the first blue light-emitting layer 4B1. The bank 11 is disposed between the first blue light-emitting layer 4B1 and the second blue light-emitting layer 4B2. The banks 9, 10, and 11 may be integrated together.

The display device 102 includes a transparent electrode 5 instead of the transparent electrodes 5R, 5G, 5B, and 5Y. The transparent electrode 5 is continuously provided over the red light-emitting layer 4R, the green light-emitting layer 4G, the first blue light-emitting layer 4B1, and the second blue light-emitting layer 4B2. The transparent electrode 5 serves as the function of the transparent electrode 5R, the function of the transparent electrode 5G, the function of the transparent electrode 5B, and the function of the transparent electrode 5Y. The yellow-wavelength conversion layer 6 is provided over the transparent electrode 5.

### Third Embodiment

FIG. 4 is a sectional view of a schematic configuration of a display device 103 according to a third embodiment of the present disclosure. The configuration of the display device 103 is the same as the configuration of the display device 101 with the exception of the following regard.

The display device 103 further includes a sealant 12 and a protective film 13. The sealant 12 is provided on the substrate 1. The sealant 12 seals the red light-emitting portion 2R, the green light-emitting portion 2G, the blue light-emitting portion 2B, and the yellow light-emitting portion 2Y. The yellow light-emitting portion 2Y has a space 14 formed between (1) the reflective electrode 3Y, second blue light-emitting layer 4B2, and transparent electrode 5Y, and (2) the yellow-wavelength conversion layer 6, and the sealant 12 is filled in the space 14.

The protective film 13 is a light-transparent film attached to the surface of the sealant 12 (in FIG. 4, furthermore to the surface of the yellow-wavelength conversion layer 6). As the result of the attachment of the protective film 13, one display surface of the display device 103 (in FIG. 4, the upper end surface of the display device 103) is flat.

The display device 103 has a flat upper end surface and a flat lower end surface, and the display device 103 is thin. The display device 103 is hence suitable when it is used as a film-shaped display device.

The aforementioned configuration of the display device 103 different from that of the display device 101 may be combined with the configuration of the display device 102.

### Fourth Embodiment

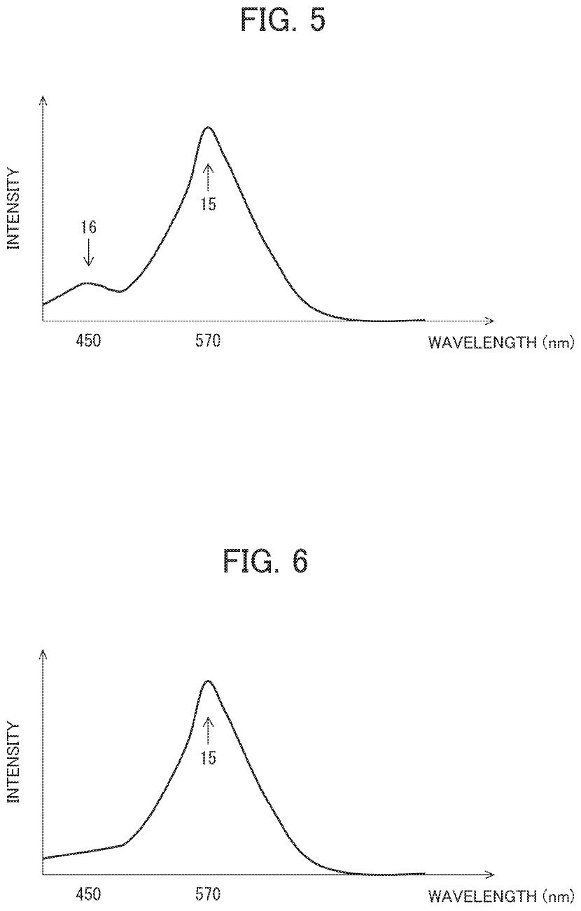

FIG. 5 is a graph showing an example spectrum of light that is emitted by the yellow light-emitting portion 2Y. FIG. 6 is a graph showing another example spectrum of light that is emitted by the yellow light-emitting portion 2Y. As illustrated in FIG. 5 and FIG. 6, the spectrum of light that is emitted by the yellow light-emitting portion 2Y having the second blue light-emitting layer 4B2 and the yellow-wavelength conversion layer 6 includes a peak 15 resulting from the yellow light Y that is emitted from the yellow-wavelength conversion layer 6.

As illustrated in FIG. 5, the spectrum of light that is emitted by the yellow light-emitting portion 2Y, having the second blue light-emitting layer 4B2 and the yellow-wavelength conversion layer 6, may include a peak 16 of a wavelength of less than 490 nm resulting from the second blue light B2 that is emitted from the second blue light-emitting layer 4B2. This enables the second blue light-emitting layer 4B2 to share part of a burden on the first blue light-emitting layer 4B1, thus reducing the burden on the first blue light-emitting layer 4B1, thus enabling the first blue light-emitting layer 4B1 to have a long life.

As illustrated in FIG. 6, the spectrum of light that is emitted by the yellow light-emitting portion 2Y, having the second blue light-emitting layer 4B2 and the yellow-wavelength conversion layer 6, does not have to include a peak (corresponding to the peak 16 in FIG. 5) of a wavelength of less than 490 nm resulting from the second blue light B2 that is emitted from the second blue light-emitting layer 4B2. This improves the monochromaticity of the yellow light Y and can thus achieve a wider-color-gamut display device.

### ADDITIONAL NOTE

Each of the display devices 101 to 103 may further include a light-scattering layer that scatters the yellow light Y emitted from the yellow-wavelength conversion layer 6. Further, the yellow-wavelength conversion layer 6 may contain a light-scattering material, or resin.

### Summary

A display device according to a first aspect of the present disclosure includes the following: a red light-emitting layer configured to emit red light, a green light-emitting layer configured to emit green light, a first blue light-emitting layer configured to emit first blue light, and a second blue light-emitting layer configured to emit second blue light, the red light-emitting layer, the green light-emitting layer, the first blue light-emitting layer, and the second blue light-emitting layer being individually provided in the cross-sectional view of the display device; and a yellow-wavelength conversion layer provided over at least the second blue light-emitting layer, and configured to convert the second blue light into yellow light.

The display device according to a second aspect of the present disclosure is configured, in the first aspect, such that the yellow-wavelength conversion layer contains a quantum dot material.

The display device according to a third aspect of the present disclosure is configured, in the second aspect, such that the quantum dot material has a core made of InP.

The display device according to a fourth aspect of the present disclosure is configured, in any one of the first to third aspects, such that Srg/Sy<Ey is satisfied, where Ey is the energy conversion efficiency of the yellow-wavelength conversion layer, where Sy is the standard photopic luminous efficiency of the yellow light, where Srg is the average between the standard photopic luminous efficiency of the red light and the standard photopic luminous efficiency of the green light.

The display device according to a fifth aspect of the present disclosure is configured, in any one of the first to fourth aspects, such that the second blue light-emitting layer is composed of a quantum-dot light-emitting diode.

The display device according to a sixth aspect of the present disclosure is configured, in any one of the first to fifth aspects, such that at least one of the red light-emitting layer and the green light-emitting layer is composed of a quantum-dot light-emitting diode.

The display device according to a seventh aspect of the present disclosure is configured, in any one of the first to sixth aspects, such that the yellow light has a peak wavelength of 570 nm, and the first blue light has a peak wavelength of 450 nm.

The display device according to an eighth aspect of the present disclosure in any one of the first to seventh aspects includes a bank disposed between the second blue light-emitting layer and a particular light-emitting layer that is the red light-emitting layer or the green light-emitting layer, wherein the yellow-wavelength conversion layer is continuously provided over the second blue light-emitting layer, the bank, and the particular light-emitting layer, and each of at least a part of the height of the yellow-wavelength conversion layer over the second blue light-emitting layer, and at least a part of the height of the yellow-wavelength conversion layer over the particular light-emitting layer is lower than the height at the peak of the bank.

The display device according to a ninth aspect of the present disclosure is configured, in any one of the first to eighth aspects, such that the spectrum of light that is emitted by a yellow light-emitting portion having the second blue light-emitting layer and the yellow-wavelength conversion layer includes a peak resulting from the second blue light.

The display device according to a tenth aspect of the present disclosure is configured, in any one of the first to eighth aspects, such that the spectrum of light that is emitted by a yellow light-emitting portion having the second blue light-emitting layer and the yellow-wavelength conversion layer does not include a peak resulting from the second blue light.

The present disclosure is not limited to the foregoing embodiments. Various modifications can be made within the scope of the claims. An embodiment that is obtained in combination as appropriate with the technical means disclosed in the respective embodiments is also included in the technical scope of the present disclosure. Furthermore, combining the technical means disclosed in the respective embodiments can form a new technical feature.

1. A display device comprising:
a red light-emitting layer configured to emit red light, a green light-emitting layer configured to emit green light, a first blue light-emitting layer configured to emit first blue light, and a second blue light-emitting layer configured to emit second blue light, the red light-emitting layer, the green light-emitting layer, the first blue light-emitting layer, and the second blue light-emitting layer being individually provided in a cross-sectional view of the display device; and
a yellow-wavelength conversion layer provided over at least the second blue light-emitting layer, and configured to convert the second blue light into yellow light.

2. The display device according to claim 1, wherein the yellow-wavelength conversion layer contains a quantum dot material.

3. The display device according to claim 2, wherein the quantum dot material has a core made of InP.

4. The display device according to claim 1, wherein Srg/Sy<Ey is satisfied, where Ey is energy conversion efficiency of the yellow-wavelength conversion layer, where Sy is standard photopic luminous efficiency of the yellow light, where Srg is an average between standard photopic luminous efficiency of the red light and standard photopic luminous efficiency of the green light.

5. The display device according to claim 1, wherein the second blue light-emitting layer is composed of a quantum-dot light-emitting diode.

6. The display device according to claim 1, wherein at least one of the red light-emitting layer and the green light-emitting layer is composed of a quantum-dot light-emitting diode.

7. The display device according to claim 1, wherein the yellow light has a peak wavelength of 570 nm, and the first blue light has a peak wavelength of 450 nm.

8. The display device according to claim 1, comprising
a bank disposed between the second blue light-emitting layer and a particular light-emitting layer that is the red light-emitting layer or the green light-emitting layer,
wherein the yellow-wavelength conversion layer is continuously provided over the second blue light-emitting layer, the bank, and the particular light-emitting layer, and
each of at least a part of a height of the yellow-wavelength conversion layer over the second blue light-emitting layer, and at least a part of a height of the yellow-wavelength conversion layer over the particular light-emitting layer is lower than a height at a peak of the bank.

9. The display device according to claim 1, wherein a spectrum of light that is emitted by a yellow light-emitting portion having the second blue light-emitting layer and the yellow-wavelength conversion layer includes a peak resulting from the second blue light.

10. The display device according to claim 1, wherein a spectrum of light that is emitted by a yellow light-emitting portion having the second blue light-emitting layer and the yellow-wavelength conversion layer does not include a peak resulting from the second blue light.
